(19) United States
(12) Patent Application Publication
(10) Pub. No.: US 2025/0096302 A1
(43) Pub. Date: Mar. 20, 2025

(54) BATTERY CELL PRESSING JIG

(71) Applicant: LG ENERGY SOLUTION, LTD., Seoul (KR)

(72) Inventors: Myung Geun OH, Daejeon (KR); Tae Gyu LEE, Daejeon (KR); Hae Won CHOI, Daejeon (KR)

(73) Assignee: LG ENERGY SOLUTION, LTD., Seoul (KR)

(21) Appl. No.: 18/291,516

(22) PCT Filed: Feb. 27, 2023
(86) PCT No.: PCT/KR2023/002710

§ 371 Date: Jan. 23, 2024

(30) Foreign Application Priority Data
Mar. 3, 2022 (KR) 10-2022-0027690

(51) Int. Cl. H01M 10/04

(52) U.S. Cl. CPC H01M 10/0481; H01M 10/0404; H01M 10/0422

(57) ABSTRACT

A battery cell pressing jig for assembling a battery cell includes a lower plate of which an upper surface is provided with a first pressing member for seating and arranging a plurality of battery cells thereon, an upper plate which is provided above the lower plate and of which a lower surface is provided with a second pressing member, on which the plurality of battery cells are seated in an arranged state, thereon, a pressing part configured to press both the upper plate and the lower plate toward the battery cell, and a plurality of sensing members coupled onto the upper plate to be electrically connected to the plurality of battery cells.

### TECHNICAL FIELD

The present invention relates to a battery cell pressing jig, and more particularly, to a battery cell pressing jig for pressing and assembling a battery cell for manufacturing a battery module.

This application claims the benefit of priority based on Korean Patent Application No. 10-2022-0027690, filed on Mar. 3, 2022, and the entire contents of the Korean patent application are incorporated herein by reference.

### BACKGROUND TECHNOLOGY OF THE INVENTION

Recently, chargeable and dischargeable secondary batteries have been widely used as energy sources of wireless mobile devices.

In addition, secondary batteries are attracting attention not only as energy sources of portable devices such as cellphones, laptop computers, and camcorders, but also as energy sources of electric vehicles and hybrid electric vehicles proposed as a solution to air pollution due to gasoline and diesel vehicles using fossil fuels.

Therefore, types of applications using secondary batteries are being variously diversified due to the advantages of the secondary batteries. In the future, secondary batteries are expected to be applied to more fields and products.

Such secondary batteries are classified into lithium ion batteries, lithium ion polymer batteries, lithium polymer batteries, and the like according to a configuration of an electrode and an electrolyte. The use of lithium ion polymer batteries, which are less likely to leak an electrolyte and easy to manufacture, is increasing.

In general, according to a shape of a battery case, secondary batteries are classified into cylindrical type batteries in which an electrode assembly is embedded in a cylindrical metal can, prismatic batteries in which an electrode assembly is embedded in a prismatic metal can, and pouch type battery cells in which an electrode assembly is embedded in a pouch type case of an aluminum laminate sheet.

An electrode assembly embedded in a battery case is a chargeable and dischargeable power generating device which has a structure including a positive electrode, a negative electrode, and a separator interposed between the positive electrode and the negative electrode. Electrode assemblies are classified into jelly-roll type electrode assemblies in which a separator is interposed between a positive electrode and a negative electrode, each of which is provided in the form of a long sheet coated with an active material, and then the positive electrode, the separator, and the negative electrode are wound, and stacked type electrode assemblies in which a plurality of positive and negative electrodes, which are formed in a certain size, are sequentially stacked with separators interposed therebetween.

Meanwhile, such a battery cell is manufactured through an assembly process of assembling the battery cell and an activation process of activating the battery cell, and in an activation operation, a process of charging/discharging the manufactured battery cell at a constant voltage is repeated several times, and finally, the battery cell having a required voltage is shipped.

Here, when a battery module is manufactured, the battery cell is assembled using a pressing jig.

In this case, when the state of the battery cell is checked in a state in which the pressing jig is assembled to the battery cell, after the pressing jig is separated from the battery cell, the presence or absence of an abnormality of the battery cell is checked.

That is, there have been problems that there is a hassle of having to separate a battery cell from a pressing jig whenever a short circuit or the like occurs in the battery cell to then measure a voltage of the battery cell, and manufacturing takes a long time.

In addition, there has been a problem that, even when a battery cell is charged or discharged, since an operation should be performed after a pressing jig is separated from a battery cell, the operation is cumbersome.

### RELATED ART DOCUMENTS

(Patent Document 1) Korean Patent Registration No. 10-1764497

### DESCRIPTION OF THE INVENTION

### Technical Problem

An object of the present invention is to provide a battery cell pressing jig capable of charging and discharging a battery cell as well as measuring a voltage of the battery cell without separation of a pressing jig when a short circuit occurs in the battery cell in a state in which the pressing jig is assembled to the battery cell for manufacturing a battery module.

### Technical Solution

A battery cell pressing jig for assembling a battery cell includes a lower plate having an upper surface is provided with a first pressing member for seating and arranging a plurality of battery cells thereon, an upper plate above the lower plate and having a lower surface is provided with a second pressing member thereon, a pressing part configured to press the upper plate and the lower plate toward the plurality of battery cells, and a plurality of sensing members coupled onto the upper plate to be electrically connected to the plurality of battery cells.

The plurality of battery cells may be cylindrical battery cells.

A plurality of first seating grooves, in which a lower outer periphery of each of the plurality of battery cells are seated, may be formed in upper surface of the first pressing member, and a plurality of second seating grooves, in which an upper outer periphery of each of the plurality of battery cells are seated, may be formed in a lower surface of the second pressing member.

The first pressing member and the second pressing member may be made of foam.

A plurality of sensing holes in which the plurality of sensing members are inserted and installed may pass through the upper plate.

Each of the plurality of sensing members may be disposed in a vertical direction corresponding to a position of an electrode terminal of a corresponding one of the plurality of battery cells seated on the first pressing member and the second pressing member.

Each of the plurality of sensing members may be a pogo pin having a conductive tip electrically connected to an electrode terminal of a corresponding one of the plurality of battery cells and is movable upwardly and downwardly by an embedded elastic member.

Each of the plurality of sensing members may be a measurement pin including a tip made of a conductive material to be electrically connected to an electrode terminal of a corresponding one of the plurality of battery cells.

The battery cell pressing jig may further include a measurement device configured to measure a current or voltage of a battery cell of the plurality of battery cells electrically connected to a sensing member of the plurality of sensing members.

The battery cell pressing jig may further include a charge/discharge device configured to charge/discharge a battery cell of the plurality of battery cells electrically connected through a sensing member of the plurality of sensing members.

Each of the first pressing member and second pressing member may have a plurality of projections around a plurality of seating grooves.

Each of the plurality of projections may have four flat side surfaces.

### Advantageous Effects

According to the present invention, when a short circuit occurs in a battery cell in a state in which a pressing jig is assembled to the battery cell for manufacturing a battery module, without separation of the pressing jig, a voltage of the battery cell can be measured, and the battery cell can also be charged or discharged. Thus, a module manufacturing time can be reduced, and the productivity of the battery module can be improved.

### BRIEF DESCRIPTION OF THE DRAWINGS

FIG. 1 is a schematic perspective view illustrating a battery cell pressing jig according to the present invention.

FIG. 2 is a schematic plan view illustrating the battery cell pressing jig according to the present invention.

FIG. 3 is a schematic side cross-sectional view illustrating the battery cell pressing jig according to the present invention.

FIG. 4 is a schematic view illustrating a state in which a sensing member is installed on the battery cell pressing jig according to one embodiment of the present invention.

FIG. 5 is a schematic view illustrating the sensing member according to one embodiment of the present invention.

FIG. 6 is a schematic view illustrating a state in which a sensing member is installed on a battery cell pressing jig according to another embodiment of the present invention.

FIG. 7 is a schematic view illustrating the sensing member according to another embodiment of the present invention.

### BEST MODE FOR CARRYING OUT THE INVENTION

Hereinafter, the present invention will be described in detail. Prior to the description, it should be understood that terms used in the present specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

It should be understood that terms such as “include” or “have” used throughout the specification of the present invention are intended to indicate the presence of a feature, number, step, operation, component, part, or a combination thereof described in the specification, and they do not preclude the possibility of the presence or addition of one or more other features or numbers, steps, operations, components, parts or combinations thereof.

Also, when a portion such as a layer, a film, an area, a plate, etc. is referred to as being “on” another portion, this includes not only the case where the portion is “directly on” another portion but also the case where still another portion is interposed therebetween. On the other hand, when a portion such as a layer, a film, an area, a plate, etc. is referred to as being “under” another portion, this includes not only the case where the portion is “directly under” another portion but also the case where still another portion is interposed therebetween. In addition, to be disposed “on” in the present application may include the case disposed at the bottom as well as the top.

### FIRST EMBODIMENT

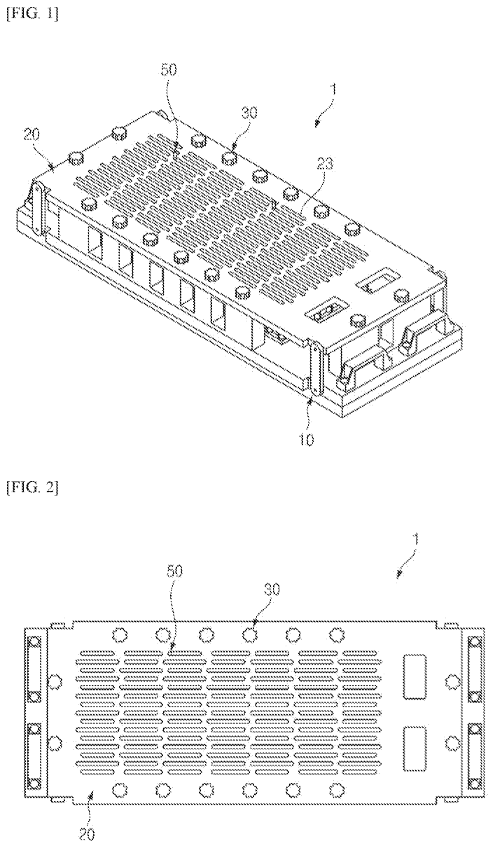

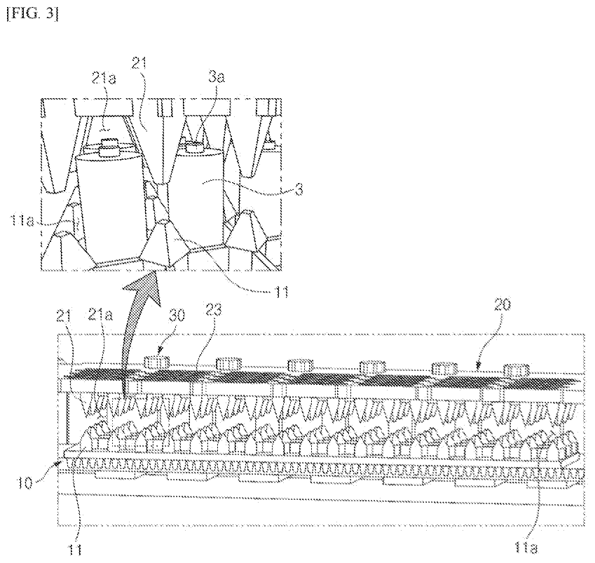

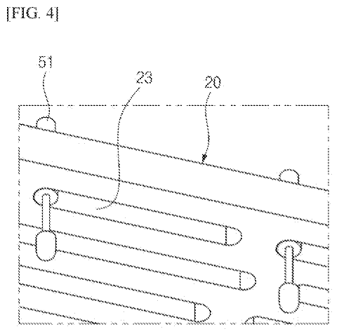

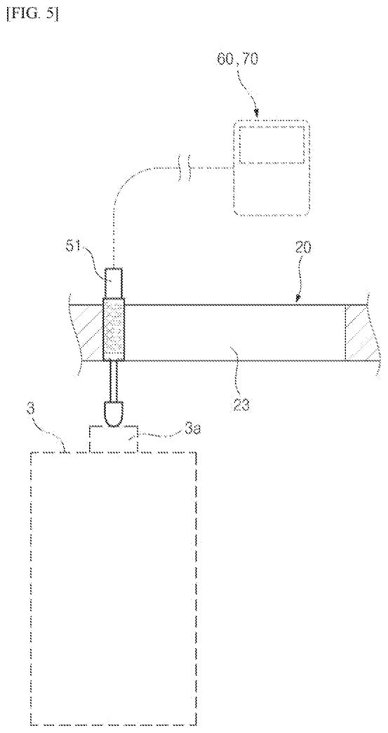

FIG. 1 is a schematic perspective view illustrating a battery cell pressing jig according to the present invention. FIG. 2 is a schematic plan view illustrating the battery cell pressing jig according to the present invention. FIG. 3 is a schematic side cross-sectional view illustrating the battery cell pressing jig according to the present invention. FIG. 4 is a schematic view illustrating a state in which a sensing member is installed on the battery cell pressing jig according to one embodiment of the present invention. FIG. 5 is a schematic view illustrating the sensing member according to one embodiment of the present invention.

A battery cell pressing jig 1 according to the present invention is for installing a plurality of battery cells 3 to manufacture a battery module and includes a lower plate 10, an upper plate 20, a pressing part 30, and sensing members 50.

A first pressing member 11 is provided on an upper surface of the lower plate 10 for the plurality of battery cells 3 to be seated and arranged.

A plurality of first seating grooves 11a are formed on an upper surface of the first pressing member 11 for a lower outer periphery of the battery cell 3 to be seated in contact therewith. An edge of the first seating groove 11a is formed to protrude upward in a shape surrounding the lower outer periphery of the battery cell 3.

The upper plate 20 is provided above the lower plate 10, and a plurality of second seating grooves 21a, with which an upper outer periphery of the battery cell 3 seated on the first pressing member 11 of the lower plate 10 is seated in contact, are formed therein.

Even in this case, an edge of the second seating groove 21a is formed to protrude downward in a shape surrounding the upper outer periphery of the battery cell 3.

In this way, in the first pressing member 11 and the second pressing member 21, the plurality of first seating grooves 11a and the plurality of second seating grooves 21a are formed in a concavely recessed shape, and the edges of the first seating groove 11a and the second seating groove 21a are formed to protrude in a pointed shape so that the battery cells 3 are easily seated and the seated battery cells 3 do not interfere with each other.

Here, the battery cell 3 may be provided as a cylindrical battery cell. Here, each of the seating grooves 11a and 21a is formed in a shape corresponding to the cylindrical battery cell for the battery cell 3 to be installed in each of the plurality of seating grooves 11a and 21a formed in the first pressing member 11 and the second pressing member 21.

Meanwhile, the first pressing member 11 and the second pressing member 21 may be made of foam having certain compressibility.

The pressing part 30 presses both the upper plate 20 and the lower plate 10 toward the battery cell 3 to fix the upper plate 20 and the lower plate 10.

Here, the pressing part 30 may be provided as a fastening member including a bolt.

A plurality of fastening holes (not shown) are formed to pass through an edge of the upper plate 20 to be spaced a certain interval apart from each other, and fastening grooves (not shown) corresponding to the fastening holes are formed at an edge of the lower plate 10.

Due to such a structure, after the fastening hole of the upper plate 20 and the fastening groove of the lower plate 10 are positioned to correspond to each other, the fastening member may be coupled to the fastening hole and the fastening groove to press the battery cell 3 installed in the upper plate 20 and the lower plate 10.

In this case, the pressing part 30 may be fastened to press the upper plate 20 against the lower plate 10, and thus the first pressing member 11 and the second pressing member 21 may come into contact with upper and lower surfaces of the battery cells 3 to press the plurality of battery cells 3, thereby resizing lengths of the battery cells 3.

The sensing members 50 are coupled onto the upper plate 20 to be electrically connected to the plurality of battery cells 3.

To this end, the sensing member 50 is in contact with and electrically connected to an electrode terminal 3a of the battery cell 3 to form an externally accessible electrical path. For example, a voltage of the battery cell 3 may be measured through the sensing member 50 without disassembling the battery cell pressing jig 1.

In addition, by using the sensing member 50, the battery cell 3 may be charged or discharged while fixed to the battery cell pressing jig 1.

In addition, the sensing member 50 may come in contact with a bus bar connecting the plurality of battery cells 3 to each other to measure voltages of the plurality of battery cells 3 and simultaneously charge/discharge the plurality of battery cells 3.

Meanwhile, a plurality of sensing holes 23 through which the sensing members 50 are inserted and installed are formed to pass through the upper plate 20.

In this way, the plurality of sensing holes 23 may be formed in the upper plate 20, and the sensing member 50 may be inserted into and installed in the sensing hole 23 formed at a position corresponding to the electrode terminal 3a of each battery cell 3, so that a voltage of the battery cell 3 can be easily measured.

Here, the sensing hole 23 may be formed in a long slot shape in a length direction of the upper plate 20 and may be formed such that the sensing member 50 is forcibly fitted and inserted therein and separated therefrom.

As described above, the plurality of sensing holes 23 are formed in the upper plate 20, and thus the sensing member 50 is disposed in a vertical upward direction corresponding to a position of the electrode terminal 3a of the battery cell 3 seated on the first pressing member 11 and the second pressing member 21.

Although the sensing hole 23 is formed in a long slot shape in one embodiment of the present invention, the sensing hole 23 may be formed in a circular shape, and a shape of the sensing hole 23 is not limited thereto.

In addition, although the sensing member 50 is detachably inserted into and installed in the sensing hole 23 in one embodiment of the present invention, the sensing member 50 may be fixed to the sensing hole 23 and provided integrally. In this case, the sensing member 50 is fixedly provided at a position corresponding to the electrode terminal 3a of the battery cell 3.

Meanwhile, the sensing member 50 is provided as a pogo pin 51 of which a conductive tip electrically connected to the electrode terminal 3a of the battery cell 3 is movable forward or backward by an embedded elastic member.

Specifically, the pogo pin 51 has a cylindrical shape, an elastic member such as a spring is installed therein, and the tip for probing the electrode terminal 3a of the battery cell 3 is made of a conductive metal material and is inserted into the sensing hole 23 of the upper plate 20 and then moved forward toward the battery cell 3 to come into elastic contact with the electrode terminal 3a, thereby making electrical connection.

As described above, since the pogo pin 51 is elastically connected to the electrode terminal 3a, electrical characteristics such as a voltage or current of the battery cell 3 can be accurately tested.

Here, the battery cell pressing jig 1 according to one embodiment of the present invention may further include a measurement device 60 electrically connected to the sensing member 50 to measure a current or voltage of the battery cell 3.

In addition, the battery cell pressing jig 1 may further include a charge/discharge device 70 that directly charges or discharges the battery cell 3 electrically connected to the sensing member 50 without removal of the battery cell pressing jig 1.

In this case, one side of the sensing member 50 exposed to the outside of the upper plate 20 may be connected to the measurement device 60 and the charge/discharge device 70 through electrical wiring to apply a current to the battery cell 3, measure a voltage of the battery cell 3, or charge/discharge the battery cell 3.

### SECOND EMBODIMENT

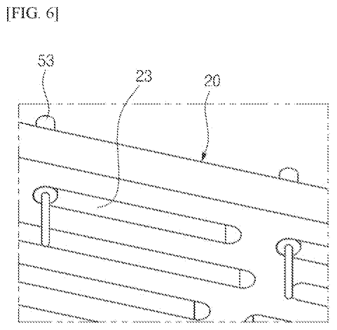

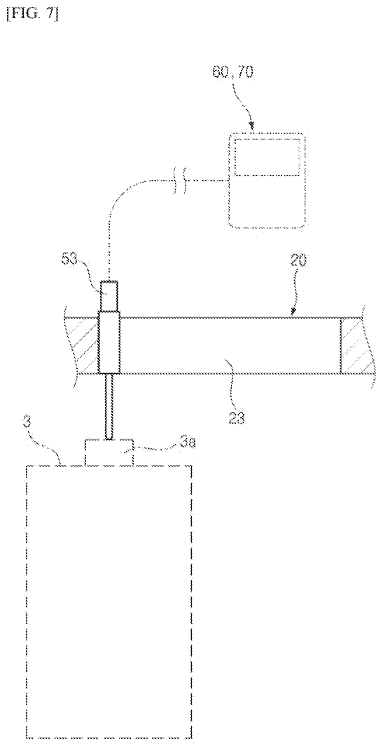

FIG. 6 is a schematic view illustrating a state in which a sensing member is installed on a battery cell pressing jig according to another embodiment of the present invention. FIG. 7 is a schematic view illustrating the sensing member according to another embodiment of the present invention.

As illustrated in FIGS. 6 and 7, a sensing member 50 according to a second embodiment is provided as a measurement pin 53 of which a conductive tip electrically connected to an electrode terminal 3a of a battery cell 3 is provided at a lower portion thereof.

Specifically, the measurement pin 53 has a rod-shaped body, a tip made of a conductive metal material to probe the electrode terminal 3a of the battery cell 3 is formed at a lower portion thereof, and a cover body made of a synthetic resin material is formed at an outer periphery thereof.

As described above, the measurement pin 53 is installed in a sensing hole 23 of an upper plate 20 and then pressed toward the battery cell 3 to bring the tip formed at the lower portion of the measurement pin 53 into contact with the electrode terminal 3a of the battery cell 3 so that the tip is electrically connected to the battery cell 3.

Although specific embodiments of the present invention have been described, it would be appreciated by those skilled in the art that various modifications and changes can be made without departing from the concept of the present invention defined by the scope of the following claims.

[Description of reference numerals]

| | |
|---|---|
| 1: battery cell press jig | 3: battery cell |
| 3a: electrode terminal | 10: lower plate |
| 11: first pressing member | 11a: first seating groove |
| 20: upper plate | 21: second pressing member |
| 21a: second seating groove | 30: pressing part |
| 50: sensing member | 51: pogo pin |
| 53: measurement pin | 60: measurement device |
| 70: charge/discharge device | |

The present invention is useful for use in manufacturing secondary batteries including cylindrical battery cells.

1. A battery cell pressing jig for assembling a battery cell, the battery cell pressing jig comprising:
a lower plate having an upper surface is provided with a first pressing member for seating and arranging a plurality of battery cells thereon;
an upper plate above the lower plate and having a lower surface provided with a second pressing member thereon;
a pressing part configured to press the upper plate and the lower plate toward the plurality of battery cells; and
a plurality of sensing members coupled onto the upper plate to be electrically connected to the plurality of battery cells.

2. The battery cell pressing jig of claim 1, wherein the plurality of battery cells are cylindrical battery cells.

3. The battery cell pressing jig of claim 1, wherein a plurality of first seating grooves, in which a lower outer periphery of each of the plurality of battery cells are seated, are formed in an upper surface of the first pressing member, and
wherein a plurality of second seating grooves, in which an upper outer periphery of each of the plurality of battery cells are seated, are formed in a lower surface of the second pressing member.

4. The battery cell pressing jig of claim 3, wherein the first pressing member and the second pressing member are made of foam.

5. The battery cell pressing jig of claim 1, wherein a plurality of sensing holes in which the plurality of sensing members are inserted and installed pass through the upper plate.

6. The battery cell pressing jig according to claim 1, wherein each of the plurality of sensing members is disposed in a vertical direction corresponding to a position of an electrode terminal of a corresponding one of the plurality of battery cells seated on the first pressing member and the second pressing member.

7. The battery cell pressing jig of claim 1, wherein each of the plurality of sensing members is a pogo pin having a conductive tip electrically connected to an electrode terminal of a corresponding one of the plurality of battery cells and is movable upwardly and downwardly by an embedded elastic member.

8. The battery cell pressing jig of claim 1, wherein each of the plurality of sensing members is a measurement pin including a tip made of a conductive material to be electrically connected to an electrode terminal of a corresponding one of the plurality of battery cells.

9. The battery cell pressing jig of claim 1, further comprising a measurement device configured to measure a current or voltage of a battery cell of the plurality of battery cells electrically connected to a sensing member of the plurality of sensing members.

10. The battery cell pressing jig of claim 1, further comprising a charge/discharge device configured to charge or discharge a battery cell of the plurality of battery cells electrically connected through a sensing member of the plurality of sensing members.

11. The battery cell pressing jig of claim 1, wherein each of the first pressing member and the second pressing member has a plurality of projections around a plurality of seating grooves.

12. The battery cell pressing jig of claim 11, wherein each of the plurality of projections has four flat side surfaces.
